(19) United States
(12) Patent Application Publication
(10) Pub. No.: US 2026/0122997 A1
(43) Pub. Date: Apr. 30, 2026

(54) NITRIDE SEMICONDUCTOR DEVICE

(71) Applicant: NATIONAL UNIVERSITY CORPORATION TOKAI NATIONAL HIGHER EDUCATION AND RESEARCH SYSTEM, Nagoya-shi (JP)

(72) Inventors: Yoshio HONDA, Nagoya-shi (JP); Hiroshi AMANO, Nagoya-shi (JP); Takeru KUMABE, Nagoya-shi (JP)

(21) Appl. No.: 18/871,979

(22) PCT Filed: Mar. 23, 2023
(86) PCT No.: PCT/JP2023/011519

§ 371 Date: Aug. 14, 2025

(30) Foreign Application Priority Data
Jun. 10, 2022 (JP) 2022-094601

(51) Int. Cl. H10D 62/824; H10D 8/60; H10D 10/80; H10D 30/47; H10D 30/66; H10D 84/85

(52) U.S. Cl. CPC H10D 62/824; H10D 8/60; H10D 10/821; H10D 30/475; H10D 30/668; H10D 84/85

(57) ABSTRACT

A nitride semiconductor device capable of enhancing device characteristics is provided. The nitride semiconductor device may comprise a polarized doped layer being a ternary nitride semiconductor and having a first conductivity type characteristic due to its compositional gradient in a thickness direction. The nitride semiconductor device may comprise a first layer of a nitride semiconductor of a second conductivity type disposed on a bottom surface of the polarized doped layer. The nitride semiconductor device may comprise a second layer of a nitride semiconductor of the second conductivity type disposed on a top surface of the polarized doped layer. The nitride semiconductor device may comprise: a first electrode disposed in electrical contact with the first layer; a second electrode disposed in electrical contact with the second layer; and a third electrode disposed in electrical contact with the polarized doped layer.

### DESCRIPTION

### Technical Field

This application claims priority based on Japanese Patent Application No. 2022-094601 filed on Jun. 10, 2022, the entire contents of which are incorporated by reference in this specification. The art disclosed herein relates to nitride semiconductor devices.

### BACKGROUND

In nitride semiconductors such as gallium nitride, p-type and n-type characteristics can be obtained by adding impurities. A related technology is described in JP 2021-28932 A.

### SUMMARY OF INVENTION

### Technical Problem

Addition of impurities causes various problems. For example, impurities scatter carriers, resulting in reduced channel mobility. Further, crystal defects generated when impurities are added degrade device characteristics.

### Solution to Technical Problem

The description herein discloses a nitride semiconductor device. The nitride semiconductor device may comprise a polarized doped layer being a ternary nitride semiconductor and having a first conductivity type characteristic due to its compositional gradient in a thickness direction. The nitride semiconductor device may comprise a first layer of a nitride semiconductor of a second conductivity type disposed on a bottom surface of the polarized doped layer. The nitride semiconductor device may comprise a second layer of a nitride semiconductor of the second conductivity type disposed on a top surface of the polarized doped layer. The nitride semiconductor device may comprise a first electrode disposed in electrical contact with the first layer. The nitride semiconductor device may comprise a second electrode disposed in electrical contact with the second layer. The nitride semiconductor device may comprise a third electrode disposed in electrical contact with the polarized doped layer.

The term “ternary nitride semiconductor” in this specification is a concept that encompasses nitride semiconductors of ternary or higher systems. Therefore, quaternary nitride semiconductors such as AlGaInN are also within the scope of the “ternary nitride semiconductors” in this specification.

According to the above, a vertical bipolar structure can be configured. Further, the polarized doped layer serving as a base can be configured in the first conductive type by its compositional gradient. Since impurities do not need to be added to the base, the various problems caused by the impurity addition can be suppressed.

The first conductivity type may be p-type. The second conductivity type may be n-type.

The compositional gradient near the top surface and the compositional gradient near the bottom surface of the polarized doped layer may be smaller than the compositional gradient at a center of the polarized doped layer in the thickness direction.

At least one of the first layer and the second layer may be a ternary nitride semiconductor, and may have a second conductivity type characteristic due to its compositional gradient in the thickness direction.

The first layer and the second layer may be doped with carrier impurities. The polarized doped layer may not be doped with intentional carrier impurities.

The description herein discloses a nitride semiconductor device. The nitride semiconductor device may comprise a substrate. The nitride semiconductor device may comprise a polarized doped layer being a ternary nitride semiconductor disposed on a top surface of the substrate and having a first conductivity type characteristic due to its compositional gradient in a thickness direction. The nitride semiconductor device may comprise a first layer of a nitride semiconductor of a second conductivity type disposed on a top surface of the polarized doped layer. The first layer may comprise a current path parallel to the substrate.

The nitride semiconductor device may further comprise a second layer of a nitride semiconductor disposed on a top surface of the first layer. The nitride semiconductor device may further comprise a first electrode and a second electrode disposed on a surface of the second layer by being separated from each other. The nitride semiconductor device may further comprise a gate electrode located between the first electrode and the second electrode and disposed on the surface of the second layer. The second layer may have a larger band gap than the top surface of the first layer.

The polarized doped layer may be AlGaN. The top surface of the polarized doped layer may be a gallium surface and a bottom surface of the polarized doped layer may be a nitrogen surface. The polarized doped layer may have the compositional gradient in which an Al composition becomes smaller toward a top surface side.

The nitride semiconductor device may further comprise a first electrode disposed on a surface of the first layer. The nitride semiconductor device may further comprise a second electrode disposed on the surface of the first layer by being separated apart from the first electrode. The nitride semiconductor device may further comprise an insulating film located between the first electrode and the second electrode and disposed in contact with the surface of the first layer. The nitride semiconductor device may further comprise a gate electrode disposed in contact with a surface of the insulating film.

The nitride semiconductor device may further comprise a first semiconductor region of a first conductivity type disposed on a surface layer of the first layer. The nitride semiconductor device may further comprise a second semiconductor region of the first conductivity type disposed on the surface layer of the first layer by being separated apart from the first semiconductor region. The first semiconductor region may be electrically connected to the first electrode. The second semiconductor region may be electrically connected to the second electrode.

The first layer may be a ternary nitride semiconductor and may have a second conductive characteristic due to its compositional gradient in the thickness direction. The compositional gradient of the first layer near the surface may be smaller than that on an inner side from the surface of the first layer.

The first conductivity type may be n-type. The second conductivity type may be p-type. The first layer may be AlGaN. A top surface of the first layer may be a gallium surface and a bottom surface of the first layer may be a nitrogen surface. The first layer may have the compositional gradient in which an Al composition becomes smaller toward a top surface side.

The first conductivity type may be n-type. The second conductivity type may be p-type. The first layer may be AlGaN. A top surface of the first layer may be a gallium surface and a bottom surface of the first layer may be a nitrogen surface. The first layer may have the compositional gradient in which an Al composition becomes larger toward a top surface side.

The description herein discloses a nitride semiconductor device. The nitride semiconductor device may comprise a drift layer of a nitride semiconductor of a first conductivity type. The nitride semiconductor device may comprise a polarized doped layer of a ternary nitride semiconductor of a second conductivity type being in contact with a top surface of the drift layer. The nitride semiconductor device may comprise a source region of a nitride semiconductor of the first conductivity type disposed above the polarized doped layer. The nitride semiconductor device may comprise a trench penetrating the polarized doped layer from a top surface of the source region and reaching the drift layer. The nitride semiconductor device may comprise a gate electrode disposed in the trench via a gate insulating film. The polarized doped layer may have a second conductivity type characteristic due to its compositional gradient in a thickness direction.

The description herein discloses a nitride semiconductor device. The nitride semiconductor device may comprise a polarized doped layer of a ternary nitride semiconductor having a first conductivity type characteristic due to its compositional gradient in a thickness direction. The nitride semiconductor device may comprise a metal layer disposed on a top surface of the polarized doped layer.

### BRIEF DESCRIPTION OF DRAWINGS

FIG. 1 is a schematic cross-sectional diagram of a semiconductor device 1.

FIG. 2 shows p-type polarization doping when a Ga polar plane is set as a main plane orientation.

FIG. 3 shows n-type polarization doping when the Ga polar plane is set as the main plane orientation.

FIG. 4 shows p-type polarization doping when a nitrogen polar plane is set as the main plane orientation.

FIG. 5 shows n-type polarization doping when the nitrogen polar plane is set as the main plane orientation.

FIG. 6 shows a schematic cross-sectional diagram of a semiconductor device 1a.

FIG. 7A shows a schematic cross-sectional diagram of a semiconductor device 201.

FIG. 7B shows a schematic cross-sectional diagram of a semiconductor device 1201 of a comparative example.

FIG. 8 shows a schematic cross-sectional diagram of a semiconductor device 301.

FIG. 9: shows a schematic cross-sectional diagram of a semiconductor device 301a.

FIG. 10 shows a schematic cross-sectional diagram of a semiconductor device 301b.

FIG. 11 shows a schematic cross-sectional diagram of a semiconductor device 401.

FIG. 12 shows a schematic cross-sectional diagram of a semiconductor device 501.

FIG. 13 shows a schematic cross-sectional diagram of a semiconductor device 601.

FIG. 14 shows a schematic cross-sectional diagram of a semiconductor device 701.

FIG. 15 shows a schematic cross-sectional diagram of a semiconductor device 501a.

FIG. 16 shows a schematic cross-sectional diagram of a semiconductor device 101a.

FIG. 17 shows a schematic cross-sectional diagram of a semiconductor device 101.

### DETAILED DESCRIPTION OF INVENTION

### First Embodiment

### (Structure of Semiconductor Device 1)

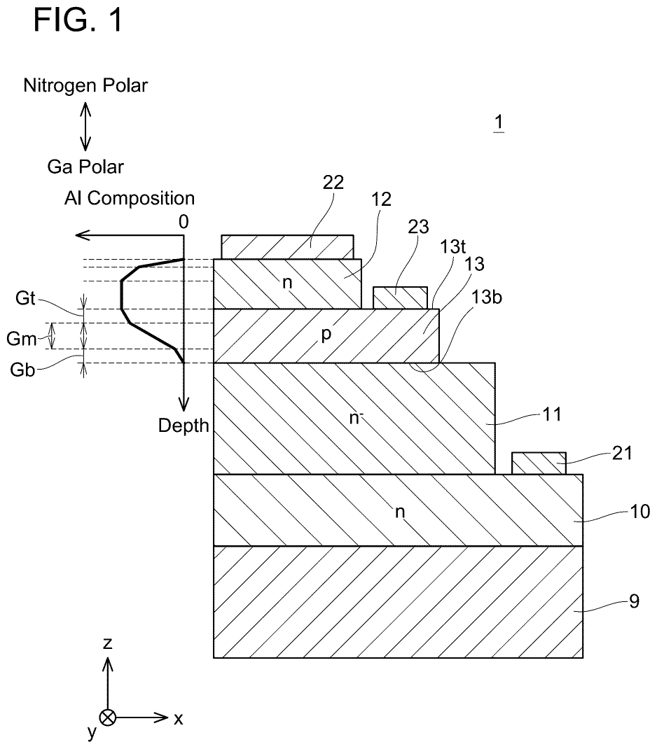

FIG. 1 shows a schematic cross-sectional diagram of a semiconductor device 1. The semiconductor device 1 is a vertical npn bipolar transistor. The semiconductor device 1 primarily comprises a support substrate 9, a growth layer 10, a first layer 11, a polarized doped layer 13, a second layer 12, a first electrode 21, a second electrode 22, and a third electrode 23. The growth layer 10, the first layer 11, the polarized doped layer 13, and the second layer 12 are layers formed on the support substrate 9 by an epitaxial growth method (e.g., MOVPE method).

The support substrate 9 is a freestanding GaN substrate. The growth layer 10 and the first layer 11 are disposed on a top surface of the support substrate 9. The growth layer 10 and the first layer 11 are n-type GaN doped with donor impurities. The first layer 11 has a lower donor impurity concentration than the growth layer 10. In this embodiment, a thickness of the first layer 11 is 0.01 to 1000 micrometer and the impurity concentration thereof is non-doped to 10²¹ units (cm⁻³).

The polarized doped layer 13 is disposed on a top surface of the first layer 11. The polarized doped layer 13 is a ternary nitride semiconductor layer that has a p-type characteristics due to its compositional gradient in a thickness direction. Further, the polarized doped layer 13 is a layer to which carrier impurities such as donor and acceptor impurities are not intentionally added. The polarized doped layer 13 may unavoidably contain donor or acceptor impurities. However, even in this case, distributed polarization doping to be described later is dominant. Examples of ternary nitride semiconductors in the description herein include semiconductors with three or more elements, and may include four or more elements. Examples of the ternary nitride semiconductor may include aluminum gallium nitride (AlGaN), indium gallium nitride (InGaN), aluminum indium nitride (AlInN), and aluminum gallium indium nitride (AlInGaN). In the present embodiment, the polarized doped layer 13 is AlGaN with a thickness of 0.01 to 10 micrometer. The specific details of the polarized doped layer 13 are described below.

The second layer 12 is disposed on a top surface of the polarized doped layer 13. The second layer 12 is n-type AlGaN. In the present embodiment, a thickness of the second layer 12 is 0.01 to 10 micrometer and an impurity concentration thereof is 10¹⁵ to 10²¹ units (cm⁻³). The specific details of the second layer 12 are described below.

A region where the first layer 11 is not disposed is formed on a top surface of the growth layer 10. The first electrode 21 is disposed on the top surface of the growth layer 10 exposed in this region. A region where the second layer 12 is not disposed is formed on the top surface of the polarized doped layer 13. The third electrode 23 is disposed on the top surface of the polarized doped layer 13 exposed in this region. Further, the second electrode 22 is disposed on a top surface of the second layer 12. The first layer 11 functions as a collector, the polarized doped layer 13 functions as a base, and the second layer 12 functions as an emitter. Further, the first electrode 31 functions as a collector electrode, the second electrode 22 functions as an emitter electrode, and the third electrode 23 functions as a base electrode.

### (Explanation on Polarized Doped Layer 13 and Second Layer 12)

The polarized doped layer 13 and the second layer 12 are layers formed by Distributed Polarization Doping (DPD). DPD is realized by AlGaN with AlN mole fraction (hereinafter referred to as “Al composition”) graded in a substrate vertical direction (z direction). Further, a film thickness of a DPD layer may be in a range of tens of nm to several micrometers.

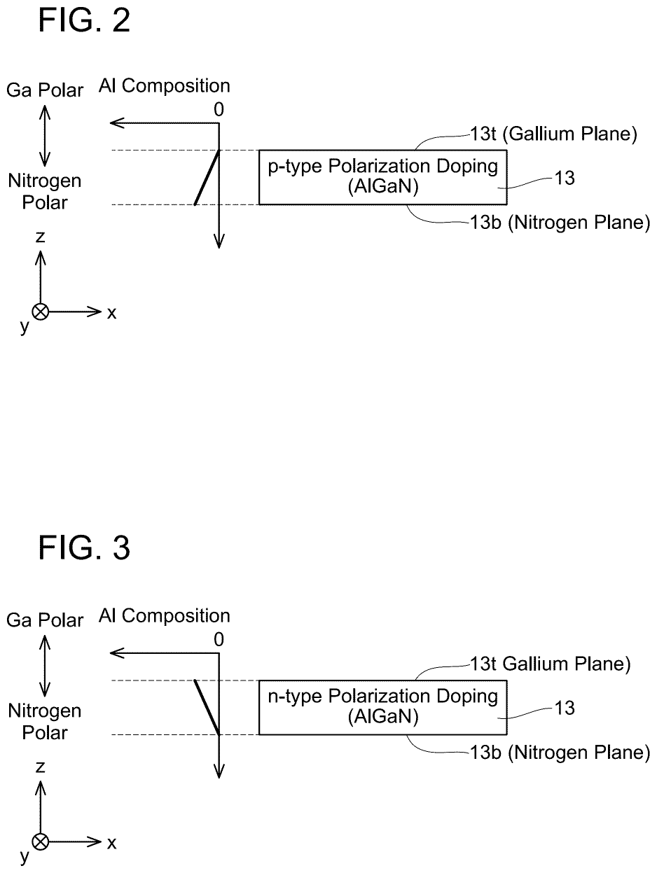

As shown in FIGS. 2 and 3, when a Ga polar plane is set as a main plane orientation (in direction), a top surface 13t is a gallium plane and a bottom surface 13b is a nitrogen plane. In this plane orientation, p-type polarization doping is performed when the compositional gradient is such that the Al composition becomes smaller on the top side (FIG. 2), and n-type polarization doping is performed when the compositional gradient is such that the Al composition becomes larger on the top side (FIG. 3).

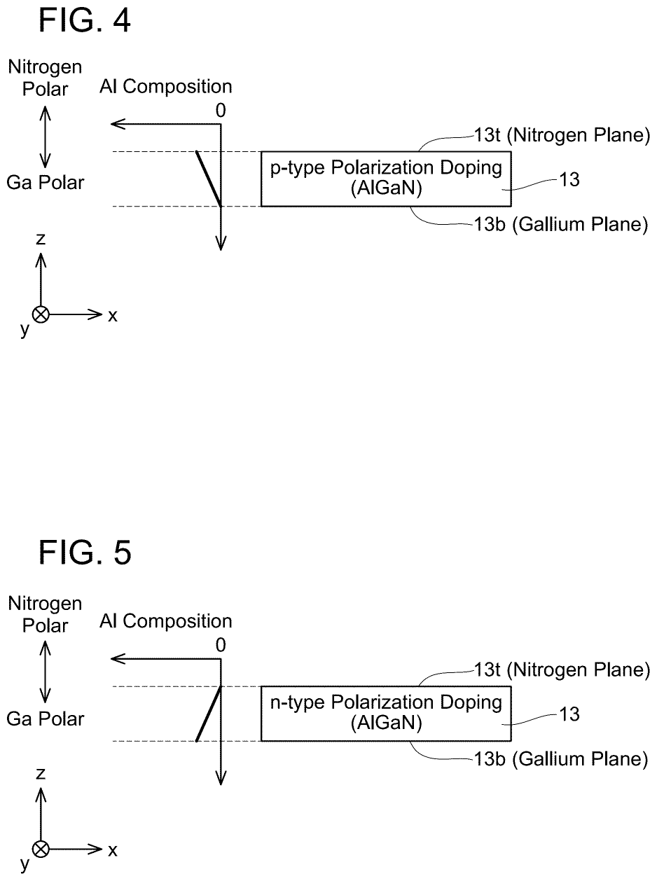

On the other hand, as shown in FIGS. 4 and 5, when a nitrogen polar plane is set as the main plane orientation (in [000-1] direction), the top surface 13t is the nitrogen plane and the bottom surface 13b is the gallium plane. In this plane orientation, p-type polarization doping is performed when the compositional gradient is such that the Al composition becomes larger on the upper side (FIG. 4), and n-type polarization doping is performed when the compositional gradient is such that the Al composition becomes smaller on the upper side (FIG. 5).

A composition distribution in the DPD layer can be controlled on the order of tens of nm. A linear compositional gradient toward the thickness direction can realize a substantially uniform charge distribution. Further, by making a slope of the compositional gradient (an amount of composition change per unit distance) larger, a spatial charge density can be increased. The compositional slope is not limited to being linear, but may be in the form of various curves. Due to this, a charge distribution that is nonlinear in the thickness direction can be generated. In the present embodiment, the composition of the DPD layer is graded so that the spatial charge density is contained in a range of about 10¹⁶ to 10²⁰ (cm⁻³). In the present embodiment, there is no intentional impurity doping in the DPD layer.

Further, in the present embodiment, as shown in FIG. 1, the p-type polarized doped layer 13 has the compositional gradient in which the nitrogen polar plane is set as the main plane orientation and the Al composition is larger on the top side. The effect is explained below. By performing the p-type polarization doping with the nitrogen polarizing plane as the main plane orientation, a mixed composition ratio can be graded so that a band gap becomes smaller (i.e., the Al composition becomes smaller) from the second layer 12 side toward the first layer 11 side. By configuring as such, an internal electric field can be generated in the polarized doped layer 13, which collects electrons toward the first layer 11. Since electrons flowing from the second layer 12 (emitter) to the first layer 11 (collector) can be accelerated, a base transit time of electrons can be improved.

Further, as shown in FIG. 1, the compositional gradient Gt near the top surface 13t and the compositional gradient Gb near the bottom surface 13b of the polarized doped layer 13 are smaller than the compositional gradient Gm near the center of the polarized doped layer 13 in the thickness direction. This allows the p-type concentration near the center of the thickness direction to be higher than the p-type concentrations respectively near the top surface 13t and the bottom surface 13b. Therefore, a depletion layer that spreads from a pn junction can be expanded in the vicinity of both the top surface 13t and the bottom surface 13b. In addition, in a region at the center of the polarized doped layer 13 in the thickness direction where the depletion layer does not expand, resistance can be reduced.

Further, the n-type second layer 12 has a nitrogen polar plane as its main plane orientation and a compositional gradient in which the Al composition is smaller on the top side.

### (Effects)

Technical problem will be explained. Conventionally, bipolar nitride semiconductor transistors have been made by doping impurities (e.g., Mg) to create a p-type layer. However, minority carrier lifetime of p-type nitride semiconductors realized by impurity doping is extremely short, which makes it difficult to achieve expected characteristics. In particular, current amplification factor cannot be increased. Further, large ionization energy of the impurity Mg results in extremely high resistance at room temperature, and this causes a reduction in operating frequency and deteriorates low power consumption performance. In addition, the impurities cause carriers to be scattered, and this results in reduced channel mobility. In addition, a memory effect of unintentional doping of Mg remaining in a chamber and impurity segregation on a crystal surface result in low controllability of p-type concentration distribution.

On the other hand, in the art disclosed in the first embodiment, the p-type polarized doped layer 13 can be fabricated with Al compositional gradient. Since there is no need to add impurities to the polarized doped layer 13, the above problem caused by adding impurities can be fundamentally suppressed. That is, the minority carrier lifetime can be significantly improved, and thus the current amplification ratio can be increased. In addition, since the p-type layer fabricated by polarization doping has no temperature dependence of free carrier concentration, it has low resistance even at room temperature, thus it is possible to increase the operating frequency and reduce power consumption. Furthermore, stable operation not different from the operation at room temperature is enabled even at extremely low and high temperatures. Further, since carrier scattering by the impurities does not occur, the reduction of channel mobility can be suppressed. Further, since memory effect and impurity segregation do not occur, control on p-type concentration distribution can be improved.

### (Variant of First Embodiment)

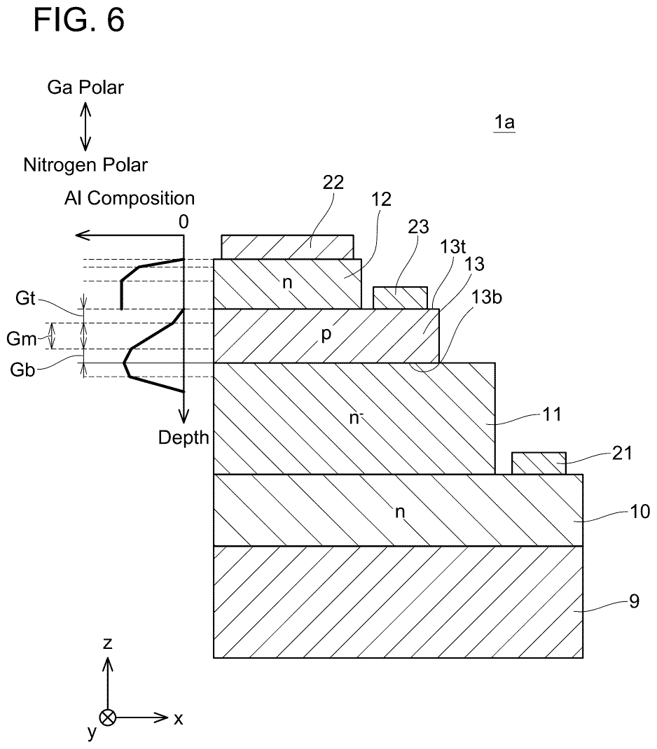

As shown in a semiconductor device 1a in FIG. 6, the main plane orientation may be a gallium polar plane. In this case, the p-type polarized doped layer 13 has a compositional gradient in which the Al composition becomes smaller on the top side. Further, the n-type second layer 12 has a compositional gradient in which the Al composition is smaller on the top side. Due to this, a potential barrier that inhibits the flow of holes from the base (polarized doped layer 13) to the emitter (second layer 12) can be generated. This makes it possible to increase the current amplification ratio of the semiconductor device 1a. Further, by setting the main plane orientation to a gallium polar plane, controllability of residual impurity concentration can be improved as compared to a case where the main plane orientation is a nitrogen polar plane. The need for purifiers and other equipment for controlling the concentration of residual impurities can be eliminated, and the yield rate can be improved. Thus, lower cost of crystal growth can be achieved and expansion of process window can be realized while obtaining the aforementioned effect of improved electron lifetime.

At least one of the first layer 11 and the second layer 12 may be a ternary nitride semiconductor. Further, by the compositional gradient in the thickness direction, the layers may have n-type characteristics. That is, in the first embodiment, the first layer 11 and the second layer 12 may be AlGaN. Further, the nitrogen polar plane may be the main plane orientation, and the compositional gradient may be such that the Al composition is smaller on the top surface side (see FIG. 5). Due to this, various problems caused by impurity addition in the first layer 11 and the second layer 12 can fundamentally be suppressed.

The conductivity type and conductivity of the support substrate 9 are not particularly limited. The support substrate 9 may be p-type, n-type, or semi-insulating. Further, when the support substrate 9 is n-type, the first electrode 21 can be disposed on the back surface of the support substrate 9.

The semiconductor device 1 may be a vertical pnp bipolar transistor. In this case, the n-type base layer may be formed with a polarized doped layer. Further, the first electrode 21 may be disposed on the back surface of the support substrate 9.

### Second Embodiment

### (Structure of Semiconductor Device 201)

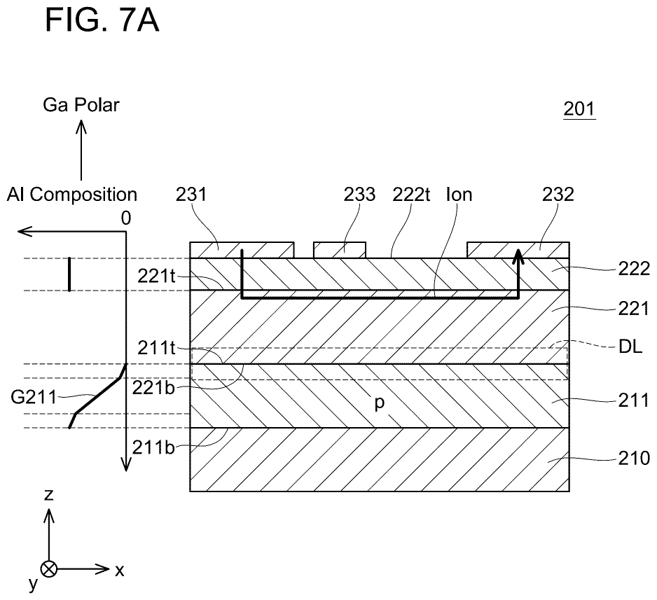

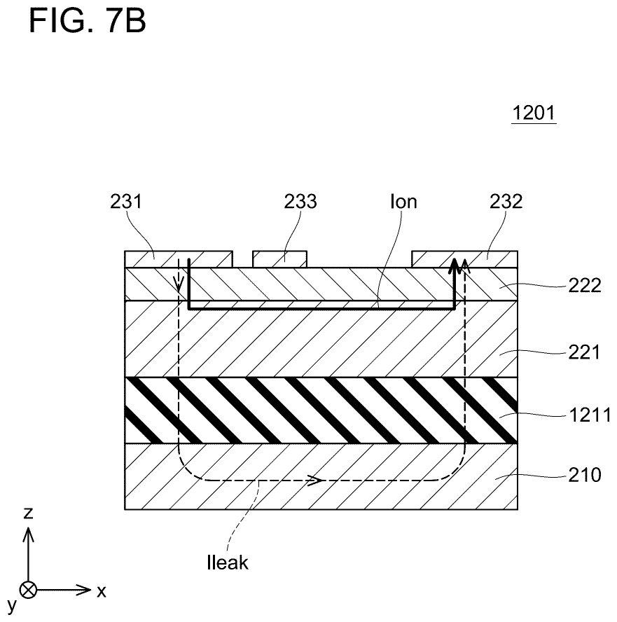

FIG. 7A shows a schematic cross-sectional diagram of a semiconductor device 201. The semiconductor device 201 is a horizontal HEMT. The semiconductor device 201 primarily comprises a support substrate 210, a polarized doped layer 211, a first layer 221, a second layer 222, a first electrode 231, a second electrode 232, and a gate electrode 233. The polarized doped layer 211, the first layer 221, and the second layer 222 are layers formed by an epitaxial growth method (e.g., MOVPE method) on the support substrate 210.

The material and conductivity type of the support substrate 210 are not particularly limited. The support substrate 210 may be, for example, Si, SiC, sapphire, or AlN. The polarized doped layer 211 is disposed on a top surface of the support substrate 210. The polarized doped layer 211 is a ternary nitride semiconductor layer that has a p-type characteristic due to its compositional gradient in a thickness direction. Further, the polarized doped layer 211 is also a layer to which no donor or acceptor impurities are intentionally added. In the present embodiment, the polarized doped layer 211 is AlGaN. The polarized doped layer 211 has a gallium polar plane as its main plane orientation. That is, a top surface 211t is the gallium plane and a bottom surface 211b is a nitrogen plane. Further, it has a compositional gradient G211 in which the Al composition is smaller on the upper 211t side.

The first layer 221 of a nitride semiconductor is disposed on the top surface of the polarized doped layer 211. In the present embodiment, the first layer 221 is GaN with no impurities intentionally added. The first layer 221 has a gallium polar plane as its main plane orientation. The second layer 222 of a nitride semiconductor is disposed on a top surface of the first layer 221. The second layer 222 is a layer with a larger band gap than the top surface 221t of the first layer 221. In the present embodiment, the second layer 222 is AlGaN. The first electrode 231 (source electrode) and the second electrode 232 (drain electrode) are spaced apart from each other on a surface 222t of the second layer 222. The gate electrode 233 is located between the first electrode 231 and the second electrode 232 on the surface 222t of the second layer 222.

Due to being induced by a heterojunction between the first layer 221 and the second layer 222, a high mobility two-dimensional electron gas (2DEG) layer is formed on a polar plane of the polarized doped layer 211. That is, the first layer 221 functions as an n-type layer. Further, the 2DEG layer can be used as a channel to flow ON-current Ion. That is, the first layer 221 has a current path parallel to the support substrate 210. Further, at the interface between the p-type polarized doped layer 211 and the n-type first layer 221, a pn junction is formed and a depletion layer DL is extended.

### (Effects)

The problems to be solved will be explained using a comparative example semiconductor device 1201 shown in FIG. 7B. Parts common to the semiconductor device 1201 of the comparative example and the semiconductor device 201 of the second embodiment are marked with common reference signs, and explanations thereof are omitted. The semiconductor device 1201 of the comparative example has an insulating layer 1211 instead of the polarized doped layer 211 of the semiconductor device 201 of the second embodiment. The insulating layer 1211 is GaN doped with impurities (e.g., carbon, iron, etc.) that compensate for free carriers. The insulating layer 1211 is a layer to suppress unintended leakage current Ileak at a lower portion of the first layer 221 when the device is OFF. However, it has been difficult to completely suppress the leakage current Ileak because the compensation effect of the insulating layer 1211 was not sufficient. In addition, impurity addition to the lower portion of the first layer 221 could cause secondary effects such as current collapses, which led to unintended characteristic degradation.

On the other hand, in the art disclosed in the second embodiment (FIG. 7A), the pn junction between the polarized doped layer 211 and the first layer 221 induces the depletion layer DL in which the free carriers are nonexistent, and a potential barrier can be formed to inhibit longitudinal conduction. Since the free carrier concentration in the depletion layer DL is lower than that in the insulating layer 1211 formed by impurity addition, the leakage current Ileak can be significantly reduced. Further, since impurity doping is not necessary to inhibit the longitudinal conduction, it becomes possible to fundamentally suppress the characteristic degradation caused by impurity doping.

In the art disclosed in the second embodiment, a p-type first layer 221 can be fabricated by Al compositional gradient. Since there is no need to add impurities to the first layer 221, it is possible to fundamentally suppress the various problems caused by the addition of impurities.

### (Variant of Second Embodiment)

The first layer 221 may be a nitride semiconductor that is configured as p-type by addition of impurities.

### Third Embodiment

### (Structure of Semiconductor Device 301)

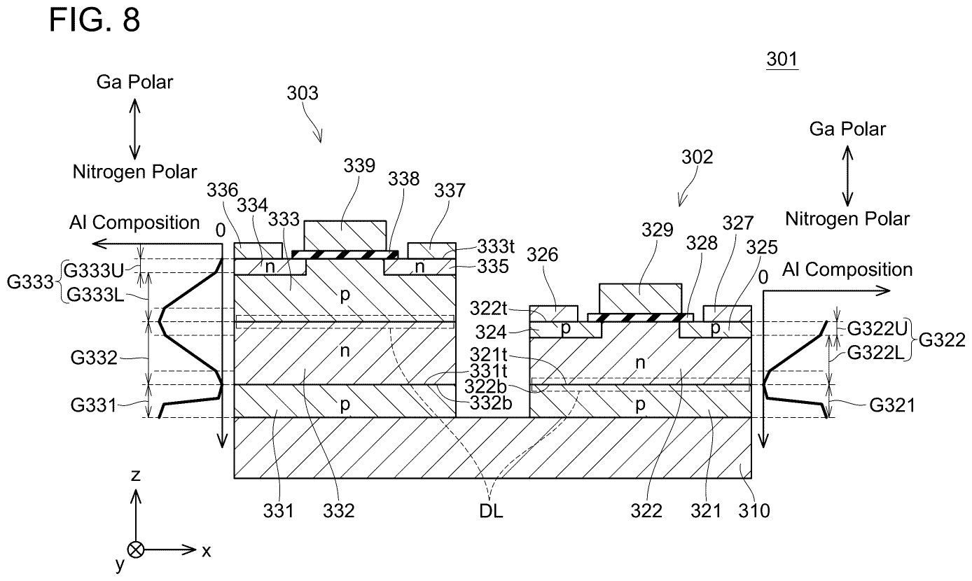

FIG. 8 shows a schematic cross-sectional diagram of a semiconductor device 301. The semiconductor device 301 is a horizontal CMOS and is in an inverted mode (normally-off). The semiconductor device 301 has a PMOS 302 and an NMOS 303. The PMOS 302 and the NMOS 303 are formed on a common support substrate 310.

The PMOS 302 has a support substrate 310, a polarized doped layer 321, a first layer 322, a first semiconductor region 324, a second semiconductor region 325, a first electrode 326, a second electrode 327, an insulating film 328, and a gate electrode 329. The support substrate 310 is a freestanding GaN substrate. The polarized doped layer 321 is disposed on a top surface of the support substrate 310. The first layer 322 is disposed on a top surface of the polarized doped layer 321. The polarized doped layer 321 and the first layer 322 are ternary nitride semiconductors and have p-type and n-type characteristics, respectively, with compositional gradients in the thickness direction. Further, the polarized doped layer 321 and the first layer 322 are layers to which impurities are not intentionally added. In the present embodiment, the polarized doped layer 321 and the first layer 322 are AlGaN.

The polarized doped layer 321 and the first layer 322 each have a gallium polar plane as its main plane orientation. The polarized doped layer 321 has a compositional gradient G321 in which the Al composition becomes smaller on a top surface 321t side, and is p-type. The first layer 322 has a compositional gradient G322 in which the Al composition is larger on a top surface 322t side, and is n-type.

The compositional gradient G322U near the top surface 322t of the first layer 322 is smaller than the compositional gradient G322L on an interior side of the top surface 322t. The area near the top surface 322t is a region where an inversion layer is formed and becomes a current path. This enables generation of an internal electric field in the first layer 322 that concentrates carriers toward the top surface 322t. Further, since alloy scattering in the current path can be suppressed, carrier mobility can be improved.

A pn junction is formed at an interface between the polarized doped layer 321 and the first layer 322, and a depletion layer DL is extended. The depletion layer DL, in which free carriers do not exist, can inhibit longitudinal conduction, thus making it possible to suppress leakage current to the support substrate 310 side.

On a surface layer of the first layer 322, the p-type first semiconductor region 324 and the p-type second semiconductor region 325 are formed separated apart from each other. The first semiconductor region 324 and the second semiconductor region 325 are regions that are configured as p-type by impurity addition. The first electrode 326 is electrically connected to and disposed on a portion of a top surface of the first semiconductor region 324. The second electrode 327 is electrically connected to a portion of a top surface of the second semiconductor region 325. The insulating film 328 is provided in contact with the surface of the first layer 322 between the first semiconductor region 324 and the second semiconductor region 325. The gate electrode 329 is provided in contact with a surface of the insulating film 328. Due to this, the first layer 322 has a current path parallel to the support substrate 310.

The NMOS 303 has a support substrate 310, a polarized doped layer 331, a polarized doped layer 332, a first layer 333, a first semiconductor region 334, a second semiconductor region 335, a first electrode 336, a second electrode 337, an insulating film 338, and a gate electrode 339. The contents of each of the polarized doped layer 331 and the polarized doped layer 332 are the same as those of the polarized doped layer 321 and the first layer 322 described above. The first layer 333 has a gallium polar plane as its main plane orientation and is p-type because it has a compositional gradient G333 in which the Al composition is larger on a top surface 333t side. The compositional gradient G333U near the top surface 333t of the first layer 333 is smaller than the compositional gradient G333L on the inner side of the top surface 333t. Due to this, an internal electric field can be generated in the first layer 333 that collects carriers toward the top surface 333t side. Further, since alloy scattering in the current path can be suppressed, carrier mobility can be improved.

A pn junction is formed at an interface between the polarized doped layer 332 and the first layer 333, and a depletion layer DL is extended. Therefore, leakage current to the support substrate 310 side can be suppressed.

On a surface layer of the first layer 333, the n-type first semiconductor region 334 and the n-type second semiconductor region 335 are formed separated apart from each other. The first semiconductor region 334 and the second semiconductor region 335 are regions that are configured n-type by adding impurities. The contents of the first electrode 336, the second electrode 337, the insulating film 338, and the gate electrode 339 are similar to the first electrode 326, the second electrode 327, the insulating film 328, and the gate electrode 329 described above. Due to this, the first layer 333 has a current path parallel to the support substrate 310.

A manufacturing method of the semiconductor device 301 is described below. A first p-type layer, an n-type layer, and a second p-type layer are stacked on the support substrate 310 in this order using a 3D polarization doping technique. The second p-type layer in a region where the PMOS 302 is to be formed is removed using well-known lithographic and dry etching techniques. Etching or ion implantation/thermal diffusion is used to electrically separate the regions where the PMOS 302 and the NMOS 303 are to be formed. By doing so, the polarized doped layer 321 and the polarized doped layer 331 are formed by the first p-type layer. By using the n-type layer, the first layer 322 and the polarized doped layer 332 are formed. The first layer 333 is formed by the second p-type layer. Thereafter, by using well-known lithographic and ion implantation techniques, the first semiconductor regions 324 and 334 and the second semiconductor regions 325 and 335 are formed. By forming the insulating films 328 and 338, the first electrodes 326 and 336, the second electrodes 327 and 337, and the gate electrodes 329 and 339 are formed, thus completing the semiconductor device 301.

### (Effects)

Wide bandgap semiconductors (e.g., GaN, SiC, Ga₂O₃, etc.) have a large ionization energy difference between the n-type and p-type impurities, and thus it is difficult to achieve equaling free carrier concentrations in both conductive types. Since the difference in characteristics between the n-type and p-type semiconductors becomes large, characteristics of complementary CMOS circuit is deteriorated. On the other hand, the art disclosed in the second embodiment allows the n-type first layer 322 and the p-type first layer 333 to be fabricated by the compositional gradient. Since the impurity doping, which causes the characteristic difference between the n-type and p-type semiconductors, can be eliminated, similar free carrier concentrations can be achieved in both conductive types. This makes it possible to realize a CMOS structure with good characteristics. Further, since carrier scattering by impurities is not generated and channel mobility can be increased, high-speed CMOS structure can be realized.

Since the n-type and p-type semiconductors fabricated by polarization doping have no temperature dependence of free carrier concentration, they can maintain the same free carrier concentration as with the room temperature under both very low and very high temperatures. As compared to a CMOS circuit fabricated using impurity doping, a CMOS circuit with superior temperature stability can be realized.

The region near the top surface 333t of the NMOS 303 is the region where the inversion layer is formed and that serves as the current path. Since the Al composition in the vicinity of the top surface 333t can be minimized, the generation of crystal defects can be minimized in the vicinity of the top surface 333t. This suppresses the degradation of device characteristics caused by defect levels.

As compared to a p-type semiconductor fabricated by impurity doping, a p-type semiconductor fabricated by polarization doping is not affected by memory effects or impurity segregation, and thus it can provide very good spatial charge density controllability. Therefore, it is possible to improve the controllability of ON-voltage in the NMOS 303 with the p-type first layer 333 as the channel.

### (Variant of Third Embodiment)

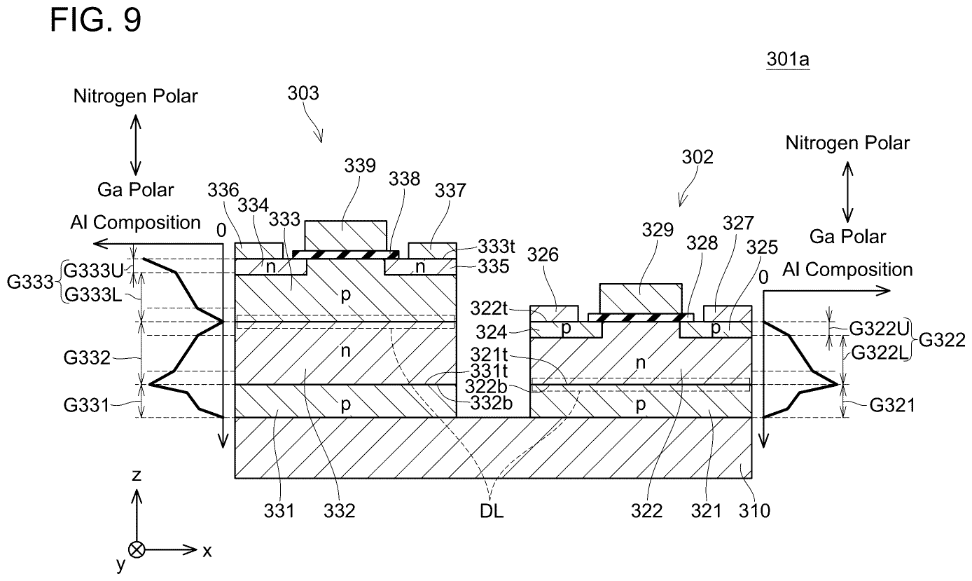

FIG. 9 shows a variant semiconductor device 301a. The semiconductor device 301a is a device in which the nitrogen polar plane is the main plane orientation in the semiconductor device 301 of FIG. 8. The compositional gradient of the semiconductor device 301a (FIG. 9) has a compositional gradient opposite to that of the semiconductor device 301 (FIG. 8). That is, the first layer 322 of the PMOS 302 has a compositional gradient G322 in which the Al composition is smaller and larger on the top surface 322t side. Further, the compositional gradient G332U on the top surface side is larger than the compositional gradient G322L on the inner side. The first layer 333 of the NMOS 303 has a compositional gradient G333 in which the Al composition is larger on the top surface 333t side. Further, the compositional gradient G333U on the top surface side is larger than the compositional gradient G333L on the inner side.

The art disclosed in the third embodiment can be applied to any device as long as the current path is parallel to the substrate. While not being limited only to HEMTs and MOS-FETs, the art is also applicable to PSJ (Polarization Superjunction)-FETs and PSJ-SBDs (Schottky Barrier Diodes), for example.

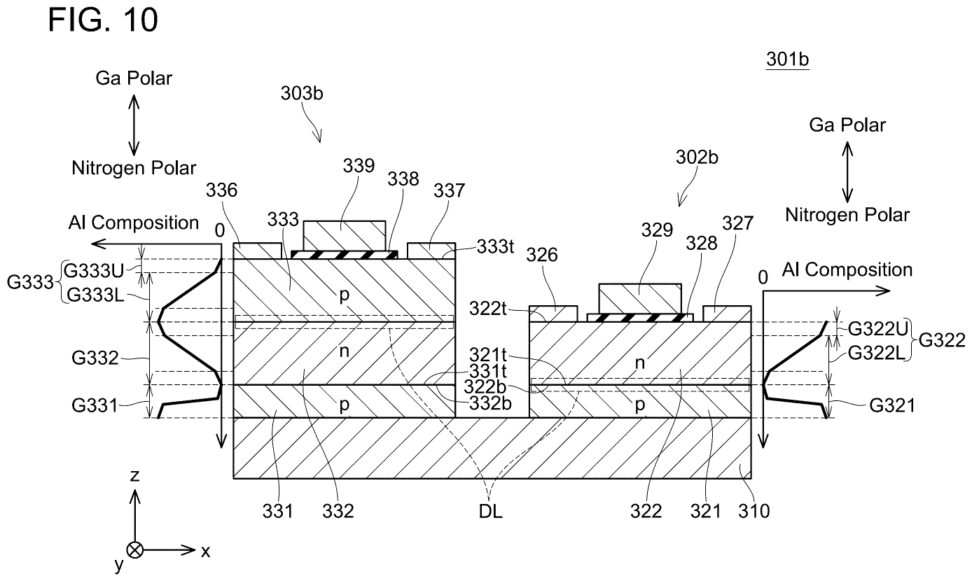

The scope of application of the third embodiment is not limited to MOS in the inverting mode (normally-off). For example, as shown in a semiconductor device 301b of FIG. 10, it can be applied to MOS in accumulation mode (normally-on). A PMOS 302b (FIG. 10) of the semiconductor device 301b does not have the first semiconductor region 324 and the second semiconductor region 325 as compared to the PMOS 302 (FIG. 8) of the semiconductor device 301. Also, an NMOS 303b (FIG. 10) of the semiconductor device 301b is not provided with the first semiconductor region 334 and the second semiconductor region 335 as compared to the NMOS 303 (FIG. 8) of the semiconductor device 301.

The scope of application of polarized doped layers is not limited to MOS structures. For example, the polarized doped layer can also be applied to MES structures that do not have the insulating films 328 and 338 and in which the gate electrodes 329 and 339 are directly disposed on the surfaces of the first layers 322 and 333.

### Fourth Embodiment

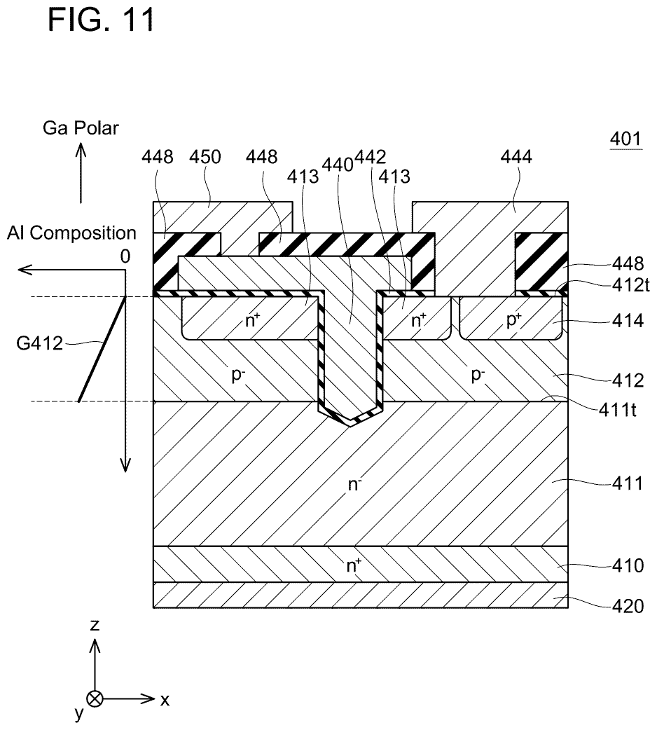

FIG. 11 shows a schematic cross-sectional diagram of a semiconductor device 401 according to a fourth embodiment. The semiconductor device 401 is a vertical MOSFET with a trench gate. A drain electrode 420 is formed on a back surface of an n⁺ type GaN drain layer 410. On a surface of the drain layer 410, a n⁻ type GaN drift layer 411 is formed. A polarized doped layer 412 is in contact with a top surface 411t of the drift layer 411. The polarized doped layer 412 is a ternary nitride semiconductor and has p-type characteristics due to its compositional gradient in the thickness direction. The polarized doped layer 412 is a layer to which no donor or acceptor impurities are intentionally added. In the present embodiment, the polarized doped layer 412 is AlGaN. The polarized doped layer 412 has a gallium polar plane as its main plane orientation. The polarized doped layer 412 has a compositional gradient G412 where the Al composition is smaller on the top 412t side.

At an upper portion of the polarized doped layer 412, an n-type source region 413 and a p-type body contact region 414 are formed by impurity addition. The trench gate electrode 440 penetrates through the polarized doped layer 412 from a top surface of the source region 413 and reaching the drift layer 411. The trench gate electrode 440 is covered on its side and bottom by a gate insulating film 442. A gate electrode 450 is in contact with trench gate electrode 440. The source electrode 444 is in contact with a top surface of a body contact region 414 and a source region 413. The source electrode 444 and the trench gate electrode 440 are insulated by the insulating film 448.

### (Effects)

The Al compositional gradient makes it possible to create a p-type polarized doped layer 412. Since there is no need to add impurities to the polarized doped layer 412, the aforementioned various problems caused by the addition of impurities can be fundamentally suppressed.

### Fifth Embodiment

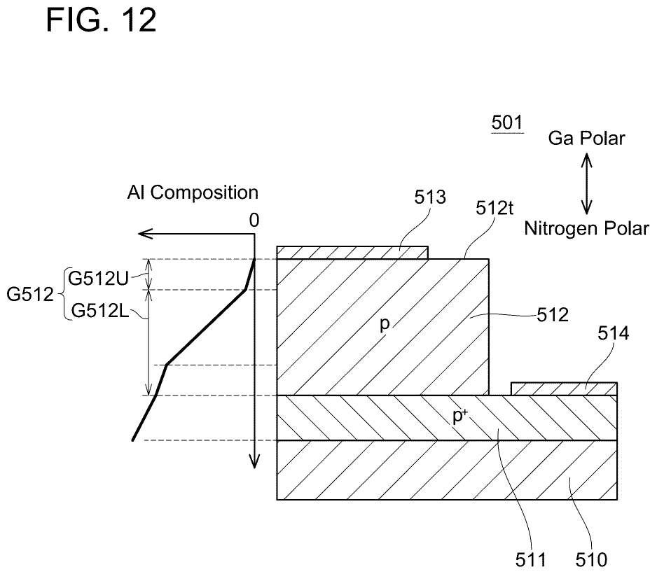

FIG. 12 shows a schematic cross-sectional diagram of a semiconductor device 501 of a fifth embodiment. The semiconductor device 501 is a Schottky barrier diode. A support substrate 510 is a freestanding GaN substrate. A first polarized doped layer 511 and a second polarized doped layer 512 are disposed on a top surface of the support substrate 510. An anode electrode 513 is disposed on a top surface of the second polarized doped layer 512. The anode electrode 513 is a metal with a small work function, for example, Ti and Al. On a top surface of the first polarized doped layer 511, a region where the second polarized doped layer 512 is not disposed is formed. A cathode electrode 514 is disposed on the top surface of this region.

The first polarized doped layer 511 and the second polarized doped layer 512 are ternary nitride semiconductors and have p-type characteristics with compositional gradient in the thickness direction. The first polarized doped layer 511 and the second polarized doped layer 512 are layers to which no impurities are intentionally added. In the present embodiment, the first polarized doped layer 511 and the second polarized doped layer 512 are AlGaN with the gallium polar plane as the main plane orientation. The second polarized doped layer 512 has a compositional gradient G512 in which the Al composition is smaller on the top surface 512t side. The compositional gradient G512U near the top surface 512t of the second polarized doped layer 512 is smaller than the compositional gradient G512L on the inner side of the top surface 510t. Due to this, a Schottky junction can be formed by the low concentration p-type layer, and a leakage current can thereby be suppressed.

### (Effects)

As compared to a Schottky junction made by impurity addition, a high free carrier concentration can be expected even at room temperature, and thus resistance can be reduced. Since a work function of p-type layer is large, the semiconductor device 501 with both a high ON-OFF ratio and low resistance can be realized.

### (Variant of Fifth Embodiment)

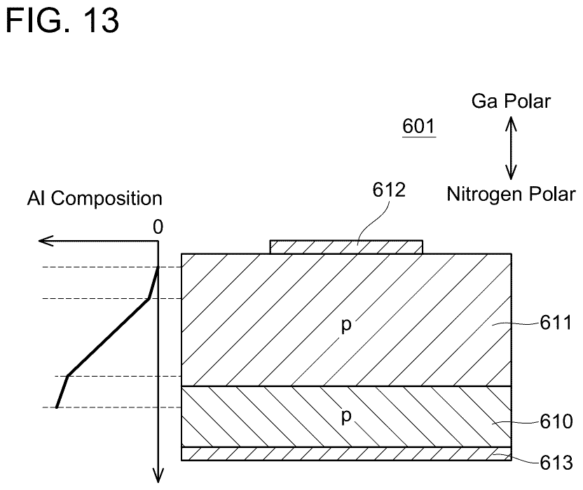

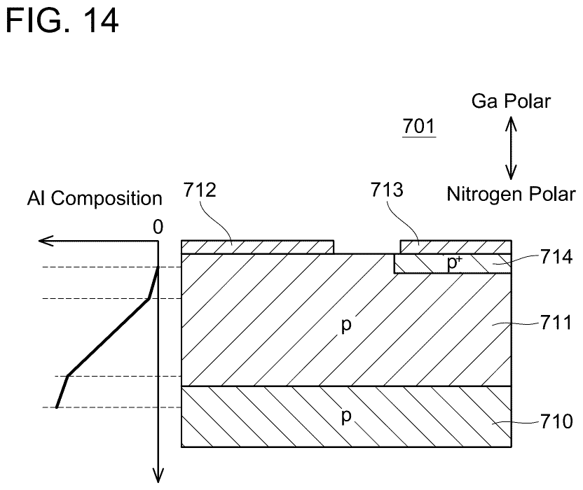

Arrangement of a cathode electrode may be configured in various ways. For example, as shown in a semiconductor device 601 in FIG. 13, a cathode electrode 613 may be provided on a back surface of a p-type substrate 610. A p-type polarized doped layer 611 and an anode electrode 612 are stacked in sequence on a top surface of the p-type substrate 610. Further, for example, as shown in a semiconductor device 701 in FIG. 14, an anode electrode 712 and a cathode electrode 713 may be disposed on a top surface of a p-type polarized doped layer 711. A contact region 714 is formed on a portion of the top surface of the polarized doped layer 711. The contact region 714 is doped with acceptor impurities so as to be configured as a highly concentrated p-type layer. A cathode electrode 713 is disposed on a top surface of the contact region 714. Further, a support substrate 710 is disposed on the bottom surface of the polarized doped layer 711.

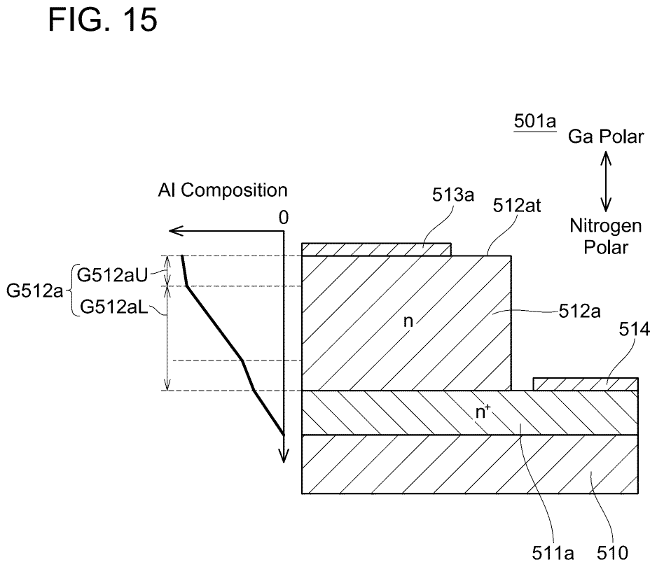

As shown in FIG. 15, a semiconductor device 501a may comprise an n-type second polarized doped layer 512a. An anode electrode 513a is disposed on a top surface 512at of the second polarized doped layer 512a. The anode electrode 513a is a metal with a large work function, for example, Ni or Pt. The second polarized doped layer 512a is AlGaN and has a compositional gradient G512a in which the Al composition is larger on the top surface 512at side. The compositional gradient G512aU on the top surface side is smaller than the compositional gradient G512aL on the inner side. Due to this, a Schottky junction can be formed with a low concentration n-type layer, thus a leakage current can be suppressed.

An embodiment of the present invention has been described in detail with reference to the drawings, however, this is a mere exemplary indication and thus does not limit the scope of the claims. The art described in the claims includes modifications and variations of the specific examples presented above.

Technical features described in the description and the drawings may technically be useful alone or in various combinations, and are not limited to the combinations as originally claimed. Further, the art described in the description and the drawings may concurrently achieve a plurality of aims, and technical significance thereof resides in achieving any one of such aims.

### (Variant)

Although the cases in which the polarized doped layer is compositionally graded in the thickness direction (perpendicular to the substrate) are described herein, the art herein is not limited to this configuration. The art described herein can also be applied to configurations in which the polarized doped layer is compositionally graded in a transverse direction (parallel to the substrate).

Although this specification describes cases in which the polarized doped layer is grown on the gallium-polarized or nitrogen-polarized surface of the GaN support substrate, the art herein is not limited to this configuration. For example, when an AlN support substrate is used, the polarized doped layer can be grown on the aluminum-polarized or nitrogen-polarized surface.

In the above embodiment, magnesium (Mg) is used as an example of the group II element to form the p-type region, however, the art herein is not limited to this configuration. The group II elements may be beryllium (Be), calcium (Ca), etc., for example.

### (Variant of Semiconductor Device 1a)

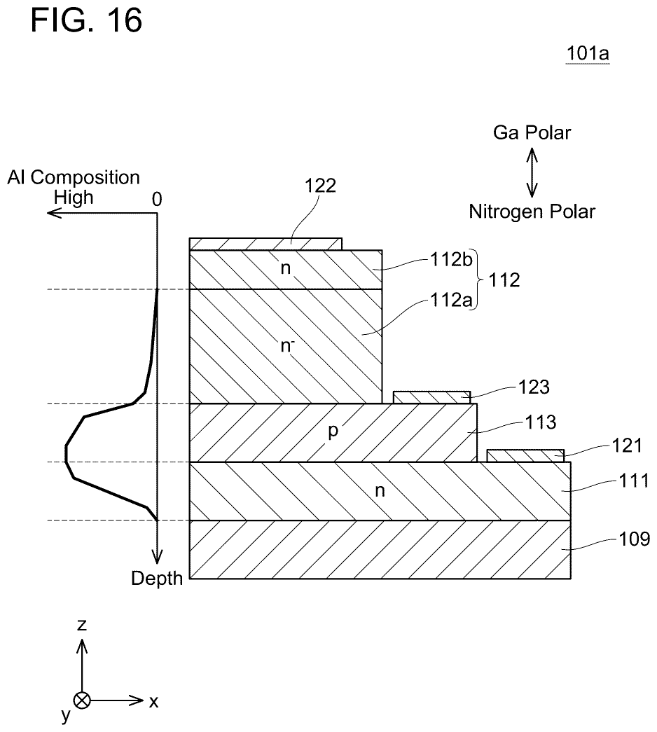

The semiconductor device 1a, which is a vertical npn bipolar transistor shown in FIG. 6, can be further modified as in a semiconductor device 101a shown in FIG. 16. As compared to the semiconductor device 1a (FIG. 6), the semiconductor device 101a (FIG. 16) has a structure in which the collector and the emitter are swapped at the top and bottom with respect to a polarized doped layer 113 at the center. Due to this, the semiconductor device 101a is more advantageous than the semiconductor device 1a in terms of higher speed.

This will be explained more specifically. A support substrate 109 is a freestanding GaN substrate. The conductivity type and conductivity of the support substrate 109 are not particularly limited. A first layer 111 is disposed on a top surface of the support substrate 109. The first layer 111 is n-type AlGaN and functions as an emitter. The first layer 111 has a compositional gradient in which its Al composition is larger on the top surface side. A polarized doped layer 113 is disposed on a top surface of the first layer 111. The polarized doped layer 113 is p-type AlGaN and functions as a base. The polarized doped layer 113 has a Ga polarization plane as its main plane orientation and a compositional gradient in which the Al composition is smaller on the top side. A second layer 112 is disposed on a top surface of the polarized doped layer 113. The second layer 112 comprises a lower second layer 112a and an upper second layer 112b. The lower second layer 112a is n-type AlGaN and functions as a drift layer. The lower second layer 112a has a compositional gradient in which the Al composition is smaller on the top side. The upper second layer 112b is n-type GaN and functions as a collector. In other words, the upper second layer 112b can be said as being AlGaN with 0% Al composition. A first electrode 121, which is an emitter electrode, is disposed on the top surface of the exposed first layer 111. A third electrode 123, which is a base electrode, is disposed on the top surface of the exposed polarized doped layer 113. Further, a second electrode 122, which is a collector electrode, is disposed on the top surface of the second layer 112.

### (Variant of Semiconductor Device 1)

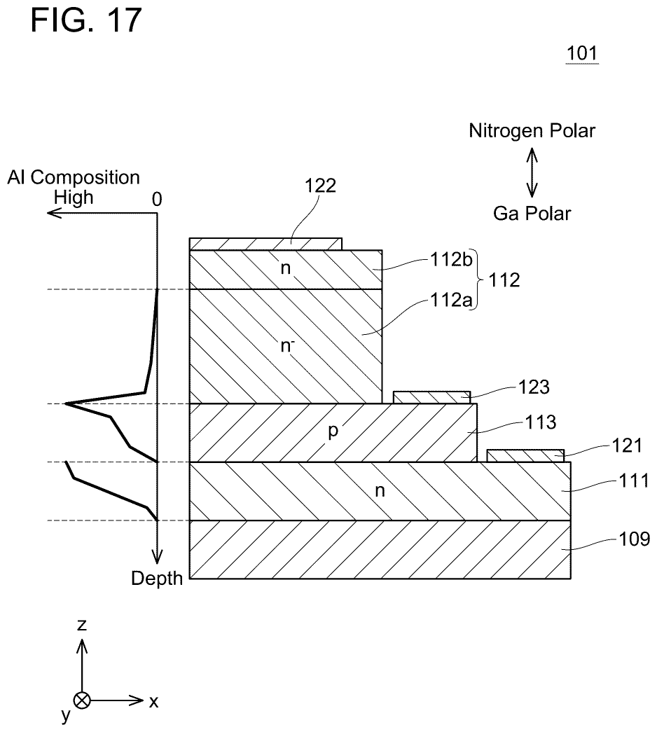

The semiconductor device 1, which is a vertical npn bipolar transistor shown in FIG. 1, can be further modified as a semiconductor device 101 shown in FIG. 17. As compared to the semiconductor device 1 (FIG. 1), the semiconductor device 101 (FIG. 17) has a structure in which the collector and emitter are swapped at the top and bottom with a polarized doped layer 113 at the center. Parts common to the semiconductor device 101 (FIG. 17) and the semiconductor device 101a (FIG. 16) are marked with common reference signs, and explanations thereof are omitted. The polarized doped layer 113 is p-type AlGaN. The polarized doped layer 113 has a nitrogen polar plane as its main plane orientation and a compositional gradient in which the Al composition is larger on the top surface side.

### (Other Variants)

The p-type and n-type concentrations of the polarized doped layers can be set higher for larger compositional gradients in the thickness direction. However, in the drawings herein, the compositional gradients of the polarized doped layers are shown schematically and may differ from the actual compositional gradients. Thus, for example, in FIG. 12, a compositional gradient of a p⁺ type first polarized doped layer 511 is larger than that of a p type second polarized doped layer 512p. Further in FIG. 15, a compositional gradient of an n⁺ type first polarized doped layer 511a is larger than that of an n type second polarized doped layer 512a. The criteria for the larger or smaller compositional gradient is relative, not absolute. For example, when two layers with different polarization doping concentrations are included in a device, as in the examples in FIG. 12 and FIG. 15, the compositional gradient is relatively larger in a higher concentration region than in a lower concentration region.

In bipolar transistors (see FIGS. 1 and 6), there may be various compositional gradients of the polarized doped layer 13 (the base region). For example, the compositional gradients Gt and Gb may be larger than the compositional gradient Gm near the center. In other words, the gradient may have a steeper slope near an interface and more gradual slope near the center. This may enhance the characteristics of the bipolar transistor.

Although the cases in which the support substrate is a freestanding substrate are described herein, the art herein is not limited to this configuration. For example, the art herein can be implemented without using a freestanding substrate when electrodes are not taken from the backside of the substrate.

When a vertical pnp bipolar transistor is to be fabricated using the art herein, the p-type emitter and collector layers may be formed with polarized doped layers. p-type layers are more difficult to produce than n-type layers in GaN-based semiconductors. This formation using the polarized doped layers is employed, because the p-type layer, which has been difficult to produce, can be realized using the polarized doped layer.

Several aspects of the present art will be listed herein below.
[Aspect 1] A nitride semiconductor device comprising:
   a polarized doped layer being a ternary nitride semiconductor and having a first conductivity type characteristic due to its compositional gradient in a thickness direction,
   a first layer of a nitride semiconductor of a second conductivity type disposed on a bottom surface of the polarized doped layer;
   a second layer of a nitride semiconductor of the second conductivity type disposed on a top surface of the polarized doped layer;
   a first electrode disposed in electrical contact with the first layer;
   a second electrode disposed in electrical contact with the second layer; and
   a third electrode disposed in electrical contact with the polarized doped layer.
[Aspect 2] The nitride semiconductor device according to aspect 1, wherein
   the first conductivity type is p-type, and
   the second conductivity type is n-type.
[Aspect 3] The nitride semiconductor device according to aspect 1 or 2, wherein
   the compositional gradient near the top surface and the compositional gradient near the bottom surface of the polarized doped layer are smaller than the compositional gradient at a center of the polarized doped layer in the thickness direction.
[Aspect 4] The nitride semiconductor device according to any one of aspects 1 to 3, wherein
   at least one of the first layer and the second layer is a ternary nitride semiconductor, and has a second conductivity type characteristic due to its compositional gradient in the thickness direction.
[Aspect 5] The nitride semiconductor device according to any one of aspects 1 to 4, wherein
   the first layer and the second layer are doped with carrier impurities, and
   the polarized doped layer is not doped with intentional carrier impurities.
[Aspect 6] A nitride semiconductor device comprising:
   a substrate;
   a polarized doped layer being a ternary nitride semiconductor disposed on a top surface of the substrate and having a first conductivity type characteristic due to its compositional gradient in a thickness direction; and
   a first layer of a nitride semiconductor of a second conductivity type disposed on a top surface of the polarized doped layer,
   wherein
   the first layer comprises a current path parallel to the substrate.
[Aspect 7] The nitride semiconductor device according to aspect 6, further comprising:
   a second layer of a nitride semiconductor disposed on a top surface of the first layer;
   a first electrode and a second electrode disposed on a surface of the second layer by being separated from each other; and
   a gate electrode located between the first electrode and the second electrode and disposed on the surface of the second layer,
   wherein
   the second layer has a larger band gap than the top surface of the first layer.
[Aspect 8] The nitride semiconductor device according to aspect 7, wherein
   the polarized doped layer is AlGaN,
   the top surface of the polarized doped layer is a gallium surface and a bottom surface of the polarized doped layer is a nitrogen surface, and
   the polarized doped layer has the compositional gradient in which an Al composition becomes smaller toward a top surface side.
[Aspect 9] The nitride semiconductor device according to aspect 6, further comprising:
   a first electrode disposed on a surface of the first layer;
   a second electrode disposed on the surface of the first layer by being separated apart from the first electrode;
   an insulating film located between the first electrode and the second electrode and disposed in contact with the surface of the first layer; and
   a gate electrode disposed in contact with a surface of the insulating film.
[Aspect 10] The nitride semiconductor device according to aspect 9, further comprising:
   a first semiconductor region of a first conductivity type disposed on a surface layer of the first layer; and
   a second semiconductor region of the first conductivity type disposed on the surface layer of the first layer by being separated apart from the first semiconductor region,
   wherein
   the first semiconductor region is electrically connected to the first electrode, and
   the second semiconductor region is electrically connected to the second electrode.
[Aspect 11] The nitride semiconductor device according to aspect 9 or 10, wherein
   the first layer is a ternary nitride semiconductor and has a second conductive characteristic due to its compositional gradient in the thickness direction, and
   the compositional gradient of the first layer near the surface is smaller than that on an inner side from the surface of the first layer.
[Aspect 12] The nitride semiconductor device according to aspect 11, wherein
   the first conductivity type is n-type,
   the second conductivity type is p-type,
   the first layer is AlGaN,
   a top surface of the first layer is a gallium surface and a bottom surface of the first layer is a nitrogen surface, and
   the first layer has the compositional gradient in which an Al composition becomes smaller toward a top surface side.
[Aspect 13] The nitride semiconductor device according to any one of aspects 9 to 11, wherein
   the first conductivity type is p-type,
   the second conductivity type is n-type,
   the first layer is AlGaN,
   a top surface of the first layer is a gallium surface and a bottom surface of the first layer is a nitrogen surface, and
   the first layer has the compositional gradient in which an Al composition becomes larger toward a top surface side.
[Aspect 14] A nitride semiconductor device comprising:
   a drift layer of a nitride semiconductor of a first conductivity type;
   a polarized doped layer of a ternary nitride semiconductor of a second conductivity type being in contact with a top surface of the drift layer;
   a source region of a nitride semiconductor of the first conductivity type disposed above the polarized doped layer;
   a trench penetrating the polarized doped layer from a top surface of the source region and reaching the drift layer; and
   a gate electrode disposed in the trench via a gate insulating film,
   wherein
   the polarized doped layer has a second conductivity type characteristic due to its compositional gradient in a thickness direction.
[Aspect 15] A nitride semiconductor device comprising:
   a polarized doped layer of a ternary nitride semiconductor having a first conductivity type characteristic due to its compositional gradient in a thickness direction; and
   a metal layer disposed on a top surface of the polarized doped layer.

1. A nitride semiconductor device comprising:
a polarized doped layer being a ternary nitride semiconductor and having a first conductivity type characteristic due to its compositional gradient in a thickness direction, a first layer of a nitride semiconductor of a second conductivity type disposed on a bottom surface of the polarized doped layer;
a second layer of a nitride semiconductor of the second conductivity type disposed on a top surface of the polarized doped layer;
a first electrode disposed in electrical contact with the first layer;
a second electrode disposed in electrical contact with the second layer; and
a third electrode disposed in electrical contact with the polarized doped layer.

2. The nitride semiconductor device according to claim 1, wherein
the first conductivity type is p-type, and
the second conductivity type is n-type.

3. The nitride semiconductor device according to claim 1, wherein
the compositional gradient near the top surface and the compositional gradient near the bottom surface of the polarized doped layer are smaller than the compositional gradient at a center of the polarized doped layer in the thickness direction.

4. The nitride semiconductor device according to claim 1, wherein
at least one of the first layer and the second layer is a ternary nitride semiconductor, and has a second conductivity type characteristic due to its compositional gradient in the thickness direction.

5. The nitride semiconductor device according to claim 1, wherein
the first layer and the second layer are doped with carrier impurities, and
the polarized doped layer is not doped with intentional carrier impurities.

6. A nitride semiconductor device comprising:
a substrate;
a polarized doped layer being a ternary nitride semiconductor disposed on a top surface of the substrate and having a first conductivity type characteristic due to its compositional gradient in a thickness direction; and
a first layer of a nitride semiconductor of a second conductivity type disposed on a top surface of the polarized doped layer,
wherein
the first layer comprises a current path parallel to the substrate.

7. The nitride semiconductor device according to claim 6, further comprising:
a second layer of a nitride semiconductor disposed on a top surface of the first layer;
a first electrode and a second electrode disposed on a surface of the second layer by being separated from each other; and
a gate electrode located between the first electrode and the second electrode and disposed on the surface of the second layer,
wherein
the second layer has a larger band gap than the top surface of the first layer.

8. The nitride semiconductor device according to claim 7, wherein
the polarized doped layer is AlGaN,
the top surface of the polarized doped layer is a gallium surface and a bottom surface of the polarized doped layer is a nitrogen surface, and
the polarized doped layer has the compositional gradient in which an Al composition becomes smaller toward a top surface side.

9. The nitride semiconductor device according to claim 6, further comprising:
a first electrode disposed on a surface of the first layer;
a second electrode disposed on the surface of the first layer by being separated apart from the first electrode;
an insulating film located between the first electrode and the second electrode and disposed in contact with the surface of the first layer; and
a gate electrode disposed in contact with a surface of the insulating film.

10. The nitride semiconductor device according to claim 9, further comprising:
a first semiconductor region of a first conductivity type disposed on a surface layer of the first layer; and
a second semiconductor region of the first conductivity type disposed on the surface layer of the first layer by being separated apart from the first semiconductor region,
wherein
the first semiconductor region is electrically connected to the first electrode, and
the second semiconductor region is electrically connected to the second electrode.

11. The nitride semiconductor device according to claim 9, wherein
the first layer is a ternary nitride semiconductor and has a second conductive characteristic due to its compositional gradient in the thickness direction, and
the compositional gradient of the first layer near the surface is smaller than that on an inner side from the surface of the first layer.

12. The nitride semiconductor device according to claim 11, wherein
the first conductivity type is n-type,
the second conductivity type is p-type,
the first layer is AlGaN,
a top surface of the first layer is a gallium surface and a bottom surface of the first layer is a nitrogen surface, and
the first layer has the compositional gradient in which an Al composition becomes smaller toward a top surface side.

13. The nitride semiconductor device according to claim 11, wherein
the first conductivity type is p-type,
the second conductivity type is n-type,
the first layer is AlGaN,
a top surface of the first layer is a gallium surface and a bottom surface of the first layer is a nitrogen surface, and
the first layer has the compositional gradient in which an Al composition becomes larger toward a top surface side.

14. A nitride semiconductor device comprising:
a drift layer of a nitride semiconductor of a first conductivity type;
a polarized doped layer of a ternary nitride semiconductor of a second conductivity type being in contact with a top surface of the drift layer;
a source region of a nitride semiconductor of the first conductivity type disposed above the polarized doped layer;
a trench penetrating the polarized doped layer from a top surface of the source region and reaching the drift layer; and
a gate electrode disposed in the trench via a gate insulating film,
wherein
the polarized doped layer has a second conductivity type characteristic due to its compositional gradient in a thickness direction.

15. A nitride semiconductor device comprising:
a polarized doped layer of a ternary nitride semiconductor having a first conductivity type characteristic due to its compositional gradient in a thickness direction; and
a metal layer disposed on a top surface of the polarized doped layer.
